(19) United States
(12) Patent Application Publication
(10) Pub. No.: US 2010/0123761 A1
(43) Pub. Date: May 20, 2010

(54) LIQUID EJECTING HEAD, LIQUID EJECTING APPARATUS, ACTUATOR DEVICE, AND METHOD FOR MANUFACTURING THE LIQUID EJECTING HEAD

(75) Inventor: Takeshi Saito, Suwa-shi (JP)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: SEIKO EPSON CORPORATION, Shinjuku-ku (JP)

(21) Appl. No.: 12/621,841

(22) Filed: Nov. 19, 2009

(30) Foreign Application Priority Data
Nov. 19, 2008 (JP) 2008-296082

(51) Int. Cl. B41J 2/045; H01L 41/22; C23C 14/34

(52) U.S. Cl. 347/71; 29/25.35; 204/192.15

(57) ABSTRACT

A liquid ejecting head includes a first layer essentially composed of silicon oxide disposed over a substrate, a second layer essentially composed of zirconium oxide formed by depositing zirconium on the first layer and thermally oxidizing the zirconium, a third layer essentially composed of zirconium oxide deposited on the second layer by sputtering, and a pressure generating element disposed over the third layer.

### BACKGROUND

1. Technical Field

The present invention relates to a liquid ejecting head ejecting liquid, a liquid ejecting apparatus, an actuator device and a method for manufacturing the liquid ejecting head.

2. Related Art

In an ink jet recording head, part of pressure generating chambers communicating with nozzle apertures are formed of a vibration plate, and the vibration plate is deformed by a piezoelectric elements to compress the ink in the pressure generating chambers, thereby ejecting ink droplets through the nozzle apertures. In practice, for example, an ink jet recording head uses deflection of a type of piezoelectric element including a lower electrode, a piezoelectric layer and an upper electrode.

The vibration plate may include a silicon oxide layer defining part of pressure generating chambers, and a zirconium oxide layer disposed on the silicon oxide layer.

For forming the zirconium oxide layer, JP-A-2005-166719 discloses the method of thermally oxidizing zirconium deposited on the silicon oxide layer by sputtering.

JP-A-09-254386 discloses the method of directly forming a zirconium oxide layer by sputtering using a zirconium oxide target.

The zirconium oxide layer formed by thermal oxidation as in the method disclosed in the above cited JP-A-2005-166719 exhibits high adhesion to the silicon oxide. However, if foreign matter is present on the silicon oxide layer, the zirconium oxide layer is often cracked undesirably from the point where the foreign matter is present.

The zirconium oxide layer directly formed by sputtering as in the method disclosed in JP-A-09-254386 can prevent the crack caused by the presence of foreign matter, but exhibits low adhesion to oxides, particularly to the silicon oxide layer. Accordingly, the zirconium oxide layer may separate undesirably to break.

These problems can arise not only in liquid ejecting heads represented by the ink jet recording head, but also in actuator devices installed in other apparatuses.

### SUMMARY

Accordingly, an advantage of some aspects of the invention is that it provides a liquid ejecting head and an actuator device that can reduce cracks, separation and other breakage of the zirconium oxide layer therein, a liquid ejecting apparatus including the liquid ejecting head, and a method for manufacturing the liquid ejecting head.

According to an aspect of the invention, a liquid ejection head is provided which includes a first layer essentially composed of silicon oxide disposed over a substrate, a second layer essentially composed of zirconium oxide formed by depositing zirconium on the first layer and thermally oxidizing the zirconium, a third layer essentially composed of zirconium oxide deposited on the second layer by sputtering, and a pressure generating element disposed over the third layer.

In this embodiment, the second layer formed by thermal oxidation ensures the adhesion to the first layer to prevent the zirconium oxide layer from separating. Even if the second layer cracks, the third layer formed by sputtering, covering the second layer 56 can suppress the spread of the crack. The words “over something such as a substrate or a layer” mentioned herein mean that it may be directly disposed on something or disposed with another member therebetween.

Preferably, the third layer has a thickness equal to or larger than the thickness of the second layer. Thus, the third layer can reliably cover cracks produced in the second layer.

According to another aspect of the invention, a liquid ejecting apparatus including the above-described liquid ejecting head is provided. The liquid ejecting apparatus can exhibit enhanced durability and reliability.

According to still another aspect of the invention, an actuator device is provided which includes a first layer essentially composed of silicon oxide disposed over a substrate, a second layer essentially composed of zirconium oxide formed by depositing zirconium on the first layer and thermally oxidizing the zirconium, a third layer essentially composed of zirconium oxide deposited on the second layer by sputtering; and a pressure generating element disposed over the third layer.

In this embodiment, the second layer formed by thermal oxidation ensures the adhesion to the first layer to prevent the zirconium oxide layer from separating. Even if the second layer cracks, the third layer formed by sputtering, covering the second layer can suppress the spread of the crack.

According to further aspect of the invention, a method for manufacturing a liquid ejecting head is provided. The method includes forming a zirconium layer essentially composed of zirconium on a silicon oxide-based first layer disposed over a substrate; thermally oxidizing the zirconium layer to form a second layer essentially composed of zirconium oxide; and depositing zirconium oxide on the second layer by sputtering, thereby forming a third layer essentially composed of zirconium oxide.

By forming the second layer by thermal oxidation, the adhesion between the zirconium oxide layer and the first layer can be enhanced to prevent the zirconium oxide layer from separating. By forming the third layer by sputtering, the third layer covers cracks that may occur in the second layer to suppress the spread of the cracks.

According to still further aspect of the invention, a method for manufacturing a liquid ejecting head is provided. The method includes forming a zirconium layer essentially composed of zirconium on a silicon oxide-based first layer disposed over a substrate; depositing zirconium oxide on the zirconium layer by sputtering, there by forming a third layer essentially composed of zirconium oxide; and subsequently thermally oxidizing the zirconium layer to form a second layer essentially composed of zirconium oxide.

By forming the second layer by thermal oxidation, the adhesion between the zirconium oxide layer and the first layer can be enhanced to prevent the zirconium oxide layer from separating. In addition, by forming the second layer by thermally oxidizing a zirconium layer after forming the third layer on the zirconium layer, the second layer can be prevented from cracking at the point where foreign matter is present during the formation of the second layer. Even if the second layer cracks, the third layer covering the second layer can suppress the spread of the crack.

Preferably, the method further includes forming a piezoelectric element by forming a first electrode, a piezoelectric layer and a second electrode over the third layer after forming the second layer and the third layer. Thus, the third layer can prevent the occurrence of cracks even if a stress is placed on the second layer for forming the piezoelectric element. If a crack occurs, the third layer can suppress the spread of the crack.

### BRIEF DESCRIPTION OF THE DRAWINGS

The invention will be described with reference to the accompanying drawings, wherein like numbers reference like elements.

FIG. 1 is an exploded perspective view of a recording head according to an embodiment of the invention.

FIG. 2A is a plan view of the recording head according to the embodiment, and

FIG. 2B is a sectional view of the recording head.

FIGS. 3A to 3E are sectional views showing a method for manufacturing the recording head according to the embodiment.

FIGS. 4A to 4C are sectional views showing steps subsequent to the step shown in FIG. 3E.

FIGS. 5A to 5C are sectional views showing steps subsequent to the step shown in FIG. 4C.

FIG. 6 is a sectional view showing a step subsequent to the step shown in FIG. 5C.

FIGS. 7A to 7D are sectional views showing a method for manufacturing a recording head according to another embodiment of the invention.

FIG. 8 is a schematic perspective view of a recording apparatus according to an embodiment of the invention.

### DESCRIPTION OF EXEMPLARY EMBODIMENTS

The invention will be further described with reference to exemplary embodiments.

### First Embodiment

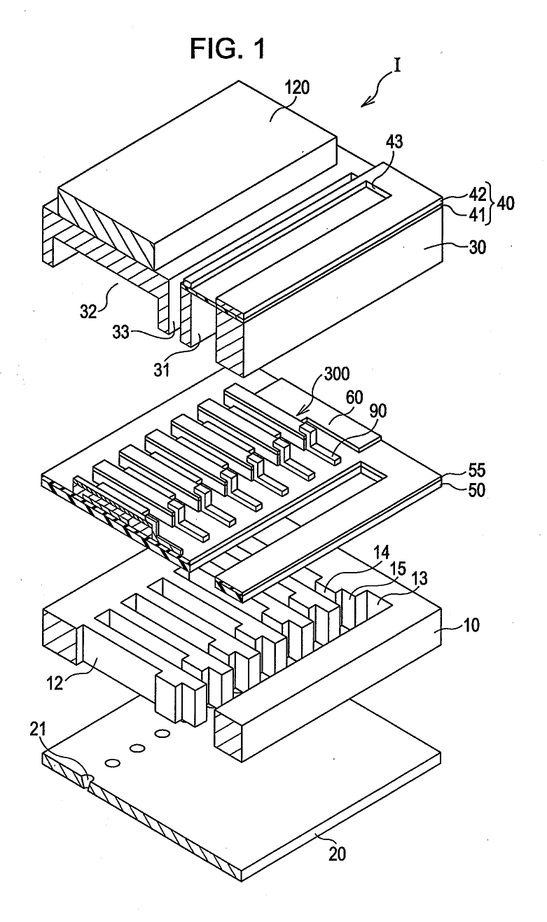

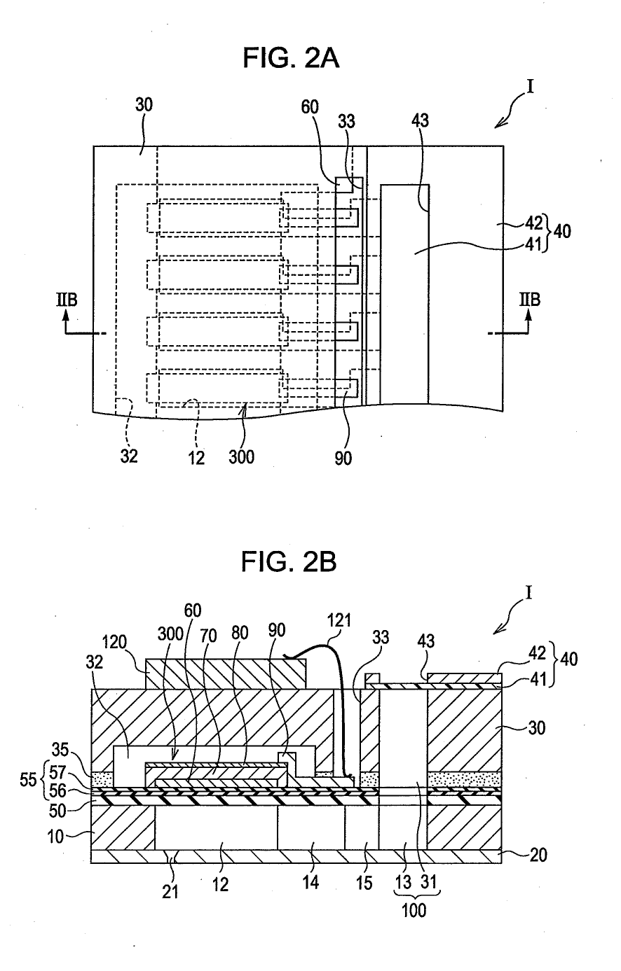

FIG. 1 is an exploded perspective view of an ink jet recording head I, which is a type of liquid ejecting head, according to a first embodiment, and FIGS. 2A and 2B are plan view of the ink jet recording head shown in FIG. 1 and a sectional view take along line IIB-IIB shown in FIG. 2A, respectively.

The ink jet recording head I includes a monocrystalline silicon flow channel substrate 10, and an elastic film 50 essentially composed of silicon oxide, which corresponds a first layer, is disposed over a surface of the flow channel substrate.

The flow channel substrate 10 has a plurality of pressure generating chambers 12 arranged in parallel. The flow channel substrate 10 also has a communicating section 13 therein in a region to the outside of the lengths of the pressure generating chambers 12, and communicates with the pressure generating chambers 12 through their respective ink supply channels 14 and communication paths 15. The communicating section 13 communicates with a reservoir section 31 formed in a protective substrate (described later) to define part of a reservoir acting as a common ink chamber of the pressure generating chambers 12. The ink supply channels 14 each have a smaller width than the pressure generating chambers 12, so that the flow resistances to the ink delivered to the pressure generating chambers 12 from the communicating section 13 is kept constant. Although the ink supply channels 14 are formed by narrowing the flow paths from one side in the present embodiment, the flow paths may be narrowed from both sides. Alternatively, the ink supply channels 414 may be formed by reducing the depth of the flow paths, instead of narrowing the flow paths.

In the present embodiment, the flow channel substrate 10 has liquid flow channels including the pressure generating chambers 12, the communicating section 13, the ink supply channels 14 and the communication paths 15.

The flow channel substrate 10 is joined with a nozzle plate 20 at the open side thereof with an adhesive, thermal fusion film or the like. The nozzle plate 20 has nozzle apertures 21 communicating with end portions of the respective pressure generating chambers 12 opposite to the ink supply channels. The nozzle plate 20 can be made of, for example, glass, ceramic, monocrystalline silicon or stainless steel.

On the other hand, an elastic film 50 is formed over the other side, opposite to the open side, of the flow channel substrate 10, and an insulating film 55 is formed on the elastic film 50. In addition, a first electrode 60, a piezoelectric layer 70 and a second electrode 80 are formed over the insulating film 55 to form piezoelectric elements 300 corresponding to pressure generating elements. Each piezoelectric element 300 mentioned herein refers to the portion including the first electrode 60, the piezoelectric layer 70 and the second electrode 80. In general, either electrode of the piezoelectric element 300 acts as a common electrode, and the other electrode and the piezoelectric layer 70 are formed for each pressure generating chamber 12 by patterning. Although in the present embodiment, the first electrode 60 acts as the common electrode of the piezoelectric elements 300 and the second electrode 80 is defined by discrete electrodes of the piezoelectric elements 300, the functions of the first and second electrodes may be reversed for the sake of convenience of the driving circuit and wiring. An actuator device used herein is defined by the piezoelectric element 300 and a vibration plate that is deformed by the operation of the piezoelectric element 300. Although in the structure shown in FIG. 1, the elastic film 50, the insulating film 55 and the first electrode 60 constitute the vibration plate, the vibration plate is not limited to this structure. For example, only the first electrode 60 may act as the vibration plate without using the elastic film 50 or the insulating film 55. The piezoelectric element 300 may double as a vibration plate.

The insulating film 55 includes a second layer 56 essentially composed of zirconium oxide formed by thermally oxidizing zirconium and a third layer 57 essentially composed of zirconium oxide formed on the second layer 56 by sputtering.

For forming the second layer 56, more specifically, a zirconium layer essentially composed of zirconium is formed on the elastic film 50, and the zirconium layer is heated to perform thermal oxidation. By forming the second layer 56 by thermal oxidation on the elastic film 50, the resulting insulating film 55 can exhibit high adhesion to the elastic film 50. Hence, the second layer 56 acts as an adhesion layer of the insulating film 55.

The third layer 57 is formed by depositing zirconium oxide directly on the second layer 56 by sputtering. The third layer 57 formed directly on the second layer 56 by sputtering can prevent the occurrence of cracks in the second layer 56. Even if the second layer 56 is cracked, the third layer 57 covers the crack to prevent the crack from spreading.

If the insulating film 55 is composed of only the third layer 57, the insulating film 55 of an oxide (zirconium oxide) is formed directly on the elastic film 50 of an oxide (silicon oxide) by sputtering. An oxide layer formed directly on an oxide by sputtering has a lower adhesion therebetween than a thermally oxidized oxide layer. In the present embodiment, the second layer 56 is formed on the elastic film 50 of an oxide (silicon oxide) by thermal oxidation so that the adhesion between the elastic film 50 and the insulating film 55 can be enhanced. Consequently, the separation between these layers during operation of the piezoelectric element 300 can be prevented, and the durability and reliability can be enhanced.

The insulating film 55 may be composed of only the second layer 56. If foreign matter is present on the elastic film 50, however, thermal oxidation causes the second layer to crack at a point where foreign matter is present. Even if the second layer is not cracked during its formation, a crack may be formed in the second layer 56 by a stress for forming the piezoelectric elements 300 or displacement of the piezoelectric elements 300 during operation. In the present embodiment, even if the second layer 56 cracks, the third layer 57 formed over the second layer 56 by sputtering covers the crack in the second layer 56 to prevent the crack from spreading. When the second layer 56 is not cracked during its formation, the second layer 56 can further be prevented from being cracked later by the stress for forming the piezoelectric elements 300 or by operating the piezoelectric elements 300 because the second layer 56 is protected by being covered with the third layer 57.

In the present embodiment, for example, the second layer 56 is formed to a thickness of 0.2 μm and the third layer 57 is formed to a thickness of 0.2 μm. Hence, the insulating film 55 has a thickness of about 0.4 μm. Preferably, the thickness of the third layer 57 is equal to or more than that of the second layer 56. In other words, it is preferably that the thickness of the second layer 56 be less than or equal to half of the total thickness of the second layer 56 and the third layer 57 (thickness of the insulating film 55). By forming the third layer 57 to a thickness equal to or more than the thickness of the second layer 56, the third layer 57 can reliably cover cracks produced in the second layer 56 and can prevent the second layer 56 from cracking.

Zirconium oxide mentioned herein includes known compounds formed by combining zirconium and oxygen, such as ZrO₂, and mixtures of zirconium oxide, zirconium and oxygen, and the second layer 56 and the third layer 57 may contain other elements as long as they are essentially composed of zirconium oxide.

Although the second layer 56 and the third layer 57 are made of the same material, their elemental ratios and crystal structures differ from each other because the second layer 56 and the third layer 57 are formed by different methods. Such differences can easily be known by analyzing the elemental ratios and crystal structures.

The piezoelectric layer 70 is formed of a piezoelectric material having an electromechanical conversion effect, particularly a metal oxide having a perovskite structure expressed by the general formula ABO₃, on the first electrode 60. Preferably, the piezoelectric layer 70 is formed of a ferroelectric material, such as lead zirconate titanate (PZT), or a ferroelectric material to which a metal oxide, such as niobium oxide, nickel oxide or magnesium oxide, is added. More specifically, materials of the piezoelectric layer 70 include lead titanate (PbTiO₃), lead zirconate titanate (Pb(Zr,Ti)O₃), lead zirconate (PbZrO₃), lead lanthanum titanate ((Pb,La)TiO₃), lead lanthanum zirconate titanate ((Pb,La)(Zr,Ti)O₃) and lead zirconium titanate magnesium niobate (Pb(Zr,Ti)(Mg,Nb)O₃). The present embodiment does not involve a particular limitation of piezoelectric material, and the effect of the embodiment can be produced without limiting the material of the piezoelectric layer 70.

The piezoelectric layer 70 has such a small thickness as the piezoelectric layer 70 does not crack in the manufacturing process, and the thickness is large to the extent that the piezoelectric layer 70 can produce displacement. For example, the piezoelectric layer 70 is formed to a thickness of about 1 to 5 μm.

Lead electrodes 90 made of, for example, gold (Au) are connected to the respective discrete second electrodes 80 of the piezoelectric elements 300 so as to extend from one ends at the ink supply channel 14 side of the second electrodes 80 to the surface of the insulating film 55.

A protective substrate 30 having a reservoir section 31 defining at least part of a reservoir 100 is joined to the flow channel substrate 10 having the piezoelectric elements 300 with an adhesive 35 so as to cover the first electrodes 60, the insulating film 55 and the lead electrodes 90. The reservoir section 31 passes through the thickness of the protective substrate 30 and extends along the widths of the pressure generating chambers 12. Thus, the reservoir section 31 communicates with the communicating section 13 of the flow channel substrate 10 to form the reservoir 100 acting as the common ink chamber of the pressure generating chambers 12. The communicating section 13 of the flow channel substrate 10 may be divided for each pressure generating chamber 12, and only the reservoir section 31 may serve as the reservoir. Alternatively, the flow channel substrate 10 may have only the pressure generating chambers 12, and the reservoir and ink supply channels 14 communicating with the respective pressure generating chambers 12 are formed in a member, such as the elastic film 50 or the insulating film 55, between the flow channel substrate 10 and the protective substrate 30.

Piezoelectric element-protecting section 32 is formed in the region corresponding to the piezoelectric elements 300 in the protective substrate 30. The Piezoelectric element-protecting section has a space so that the piezoelectric elements 300 can operate without interference. The space of the piezoelectric element-protecting section 32 is intended to ensure the operation of the piezoelectric elements 300, and may or may not be sealed.

Preferably, the protective substrate 30 is made of a material having substantially the same thermal expansion coefficient as the flow channel substrate 10, such as glass or ceramic. In the present embodiment, the protective substrate 30 is made of the same monocrystalline silicon as the flow channel substrate 10.

The protective substrate 30 has a through hole 33 passing through the thickness of the protective substrate 30. The respective lead electrodes 90 extending from the piezoelectric elements 300 are exposed in the through hole 33.

A driving circuit 120 is fixed on the protective substrate 30 to drive the piezoelectric elements 300 arranged in parallel. The driving circuit 120 may be a circuit board or a semiconductor integrated circuit (IC). The driving circuit 120 is electrically connected to each lead electrode 90 with an electroconductive connection wire 121, such as bonding wire.

Furthermore, a compliance substrate 40 including a sealing film 41 and a fixing plate 42 is joined on the protective substrate 30. The sealing film 41 is made of a flexible material having a low rigidity, and seals one side of the reservoir section 32. The fixing plate 42 is made of a relatively hard material. The portion of the fixing plate 42 opposing the reservoir 100 is completely removed in the thickness direction to form an opening 43; hence only the flexible sealing film 41 seals the one side of the reservoir 100.

The ink jet recording head of the present embodiment draws an ink through an ink inlet connected to an external ink supply means (not shown). The ink is delivered to fill the spaces from the reservoir 100 to the nozzle apertures 21. Then, the ink jet recording head applies a voltage between the first electrode 60 and each second electrode 80 corresponding to the pressure generating chambers 12, according to the recording signal from the driving circuit 120. Thus, the elastic film 50, the insulating film 55, the first electrode 60 and the piezoelectric layers 70 are deflected to increase the internal pressure in the pressure generating chambers 12, thereby ejecting the ink from the nozzle apertures 21.

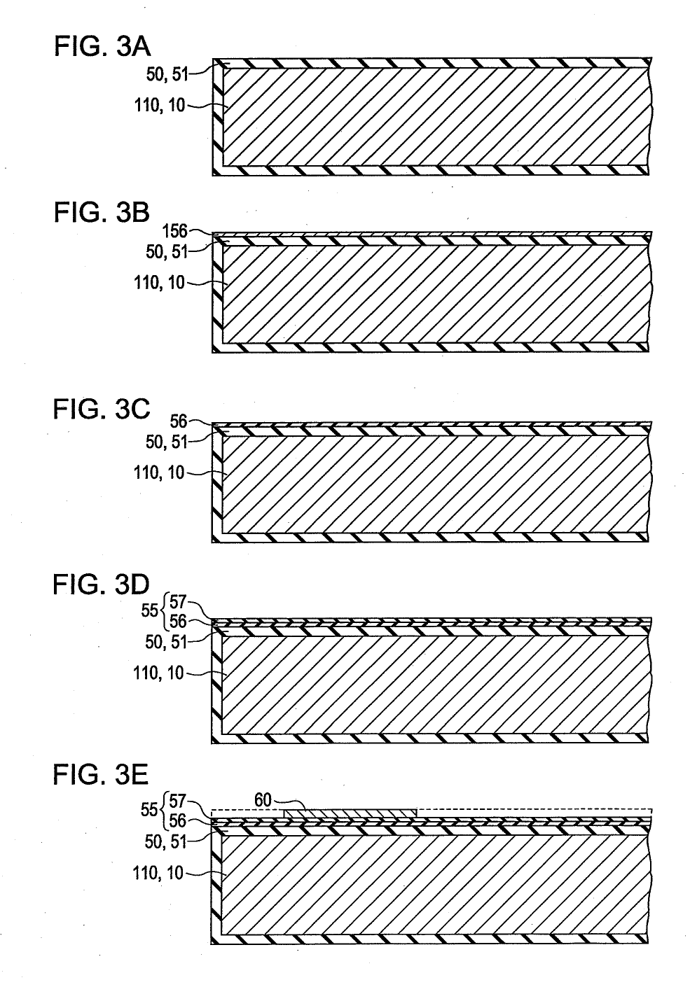

A method for manufacturing the ink jet recording head will now be described with reference to FIGS. 3A to 3E, 4A to 4C, 5A to 5C, and 6. These figures are sectional views showing a method for manufacturing the ink jet recording head being a type of liquid ejecting head according to an embodiment of the invention, taken in the longitudinal direction of the pressure generating chamber.

As shown in FIG. 3A, first, an oxide film 51 for the elastic film 50 is formed over the surface of a flow channel substrate silicon wafer 110 in which a plurality of flow channel substrates 10 are to be formed integrally. In the present embodiment, the oxide film 51 is formed by thermally oxidizing the flow channel substrate silicon wafer 110, and the oxide film 51 is thus of silicon dioxide.

Then, a second layer 56 of zirconium oxide is formed on the elastic film 50 (oxide film 51). More specifically, a zirconium layer 156 essentially composed of zirconium is formed on the elastic film 50 by, for example, sputtering, as shown in FIG. 3B, and then, the zirconium layer 156 is thermally oxidized to form the second layer 56 essentially composed of zirconium oxide in, for example, a diffusion furnace of 500 to 1200° C., as shown in FIG. 3C.

Turning now to FIG. 3D, a third layer 57 essentially composed of zirconium oxide is formed on the second layer 56. More specifically, the third layer 57 is formed by depositing zirconium oxide directly on the second layer 56 by sputtering. Thus, an insulating film 55 is formed including the second layer 56 and the third layer 57.

Then, a first electrode 60 is formed over the entire surface of the insulating film 55 and is patterned into a predetermined shape, as shown in FIG. 3E. If the piezoelectric layer 70 is made of lead zirconate titanate (PZT), preferably, the first electrode 60 is made of, but not limited to, a material whose electric conductivity is not varied much by the diffusion of lead oxide. Accordingly, for example, platinum and iridium are suitable as the material of the first electrode 60. The first electrode 60 is formed by, for example, sputtering or PVD (physical vapor deposition).

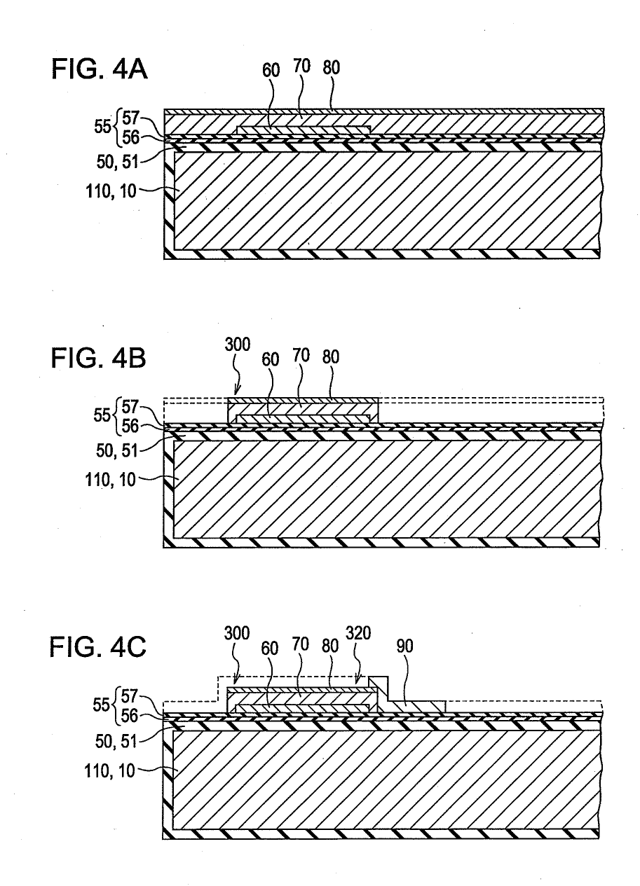

Turning now to FIG. 4A, a piezoelectric layer 70 of, for example, lead zirconate titanate (PZT) and a second electrode 80 of, for example, iridium are formed over the entire surface of the flow channel substrate wafer 110. In the present embodiment, the piezoelectric layer 70 is formed by a so-called sol-gel method. In the sol-gel method, a sol containing an organic metal dissolved or dispersed therein is applied onto a surface and dried into a gel coating, and the gel coating is fired at a high temperature to form a metal oxide piezoelectric layer 70. The piezoelectric layer 70 can be formed by any method without particular limitation, and may be formed by, for example, MOD (Metal-Organic Decomposition), or PVD (Physical Vapor Deposition) such as sputtering or laser ablation.

Turning now to FIG. 4B, the second electrode 80 and the piezoelectric layer 70 are simultaneously etched to form piezoelectric elements 300 in the region corresponding to the pressure generating chambers 12. The etching of the second electrode 80 and the piezoelectric layer 70 can be performed by dry etching, such as reactive ion etching or ion milling.

Then, a gold (Au) layer for the lead electrodes 90 is formed over the entire surface of the flow channel substrate wafer 110, and is patterned into a plurality of lead electrodes 90 for the respective piezoelectric elements 300, as shown in FIG. 4C.

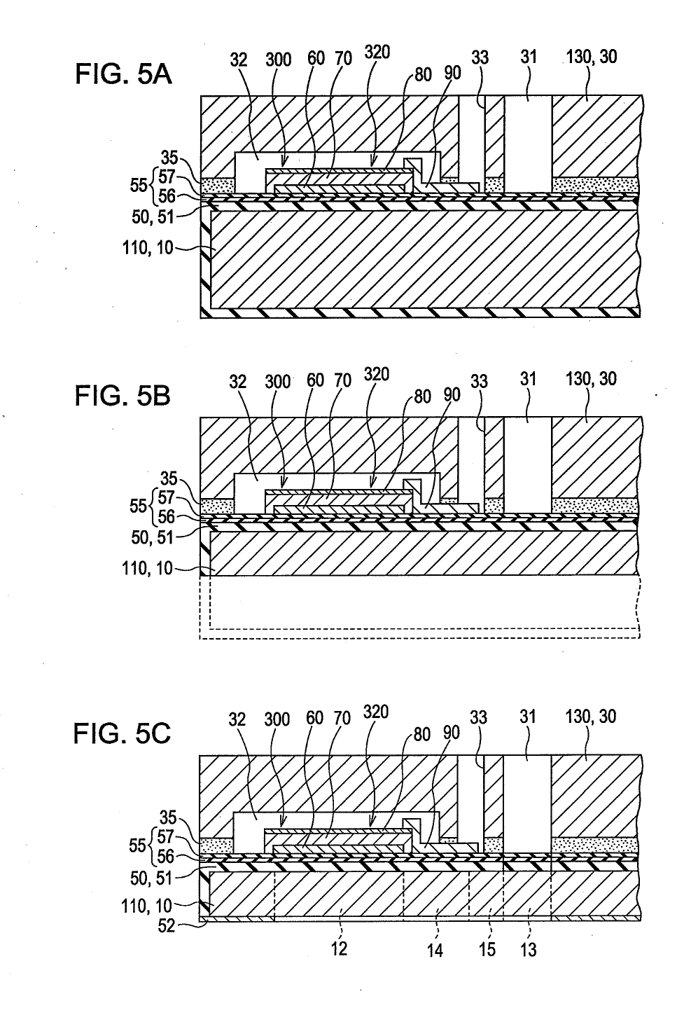

Turning now to FIG. 5A, a protective substrate wafer 130 is bonded to the flow channel substrate wafer 110 with an adhesive 35. The protective substrate wafer 130 includes a plurality of protective substrates 30 therein, including the reservoir sections 31 and the piezoelectric element-protecting sections 32. By joining the protective substrate wafer 130, the rigidity of the flow channel substrate wafer 110 is considerably enhanced.

Subsequently, the thickness of the flow channel substrate wafer 110 is reduced to a predetermined level, as shown in FIG. 5B.

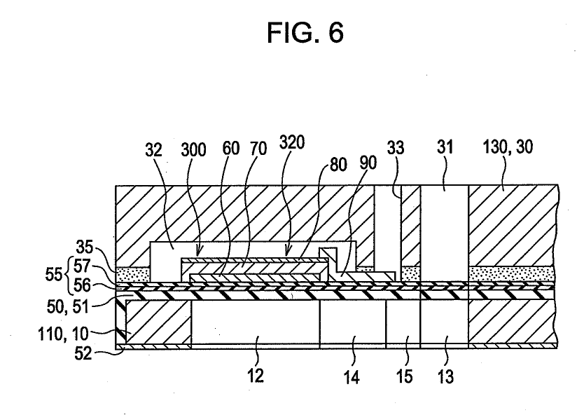

Then, a layer for a mask 52 is formed on a surface of the flow channel substrate wafer 110 opposite to the protective substrate wafer 130 and is patterned into a predetermined shape, as shown in FIG. 5C. Turning to FIG. 6, the flow channel substrate wafer 110 is subjected to anisotropic etching (wet etching) using an alkaline solution, such as KOH, through the mask 52, and thus, the pressure generating chambers 12 corresponding to the piezoelectric elements 300, the communicating section 13, the ink supply channels 14 and the communication paths 15 are formed.

Then, the mask 52 is removed from the flow channel substrate wafer 110, and unnecessary outer portions of the flow channel substrate wafer 110 and the protective substrate wafer 130 are cut off by, for example, dicing. Subsequently, a nozzle plate 20 having nozzle apertures 21 therein is joined to the surface of the flow channel substrate wafer 110 opposite to the protective substrate wafer 130, and a compliance substrate 40 is joined to the protective substrate wafer 130. The flow channel substrate wafer 110 joined with other substrates together is cut into chips, each including a flow channel substrate 10 and other members, and thus an ink jet recording head according to the present embodiment is produced.

In the manufacturing method of the ink jet recording head I according to the present embodiment, a zirconium-based zirconium layer 156 is formed on an elastic film 50, and the zirconium layer 156 is thermally oxidized by heating, as described above. Consequently, the adhesion between the elastic film 50 and the insulating film 55 can be enhanced to prevent the separation between those layers during operation of the piezoelectric element 300, and thus the durability and reliability can be enhanced.

Furthermore, the third layer 57 formed directly on the second layer 56 by sputtering can reduce the occurrence of cracks in the second layer 56. Even if the second layer 56 is cracked, the third layer 57 covers the crack to prevent the crack from spreading.

### Second Embodiment

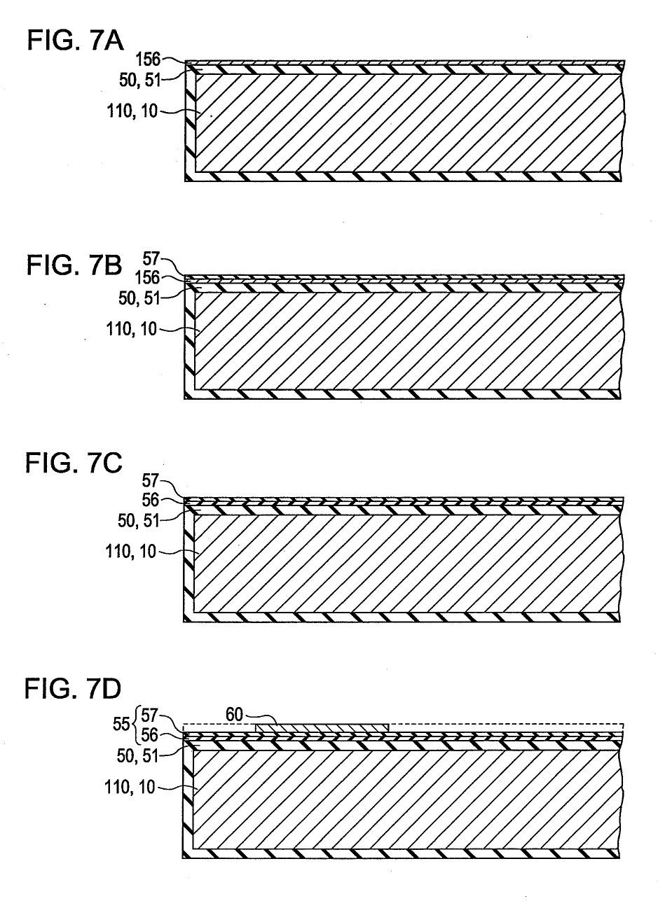

FIGS. 7A to 7D are sectional views showing a method for manufacturing an ink jet recording head being a type of liquid ejecting head according to another embodiment of the invention, taken in the longitudinal direction of the pressure generating chamber. The same parts as in the first embodiment are designated by the same reference numerals and the same description will not be repeated.

As in the step shown in FIG. 3A, an elastic film 50 is formed over the surface of the flow channel substrate wafer 110.

Subsequently, a zirconium layer 156 essentially composed of zirconium is formed on the elastic film 50, as shown in FIG. 7A. The zirconium layer 156 can be formed by, for example, sputtering or CVD.

Turning to FIG. 7B, a third layer 57 essentially composed of zirconium oxide is formed on the zirconium layer 156. The third layer 57 is formed by directly depositing zirconium oxide on the zirconium layer 156 by sputtering, as in the first embodiment.

Then, as shown in FIG. 7C, a second layer 56 essentially composed of zirconium oxide is formed by thermally oxidizing the zirconium layer 156, as shown in FIG. 7C. Although the surface of the zirconium layer 156 is covered with the third layer 57, the heated third layer 57 allows the permeation of oxygen and, thus, the zirconium layer can be thermally oxidized.

The subsequent steps including forming the piezoelectric element 300, binding the protective substrate wafer 130, and forming the pressure generating chambers 12 are performed in the same manner as in the first embodiment, and the same descriptions will be omitted.

In the second embodiment, the third layer 57 is formed on the zirconium layer 156 before thermally oxidizing the zirconium layer 156 to form the second layer 56. Therefore, the third layer 57 reinforces the zirconium layer 156 to prevent the second layer 56 from cracking at the point of foreign matter on the elastic film 50 when the zirconium layer 156 is thermally oxidized. Even if the second layer 56 cracks, the third layer 57 covering the second layer 56 can suppress the spread of the crack.

Although the method of the second embodiment is different from that of the first embodiment, the resulting ink jet recording head 1 has the same structure and accordingly produces the same effects; hence, the second layer 56 enhances the adhesion to the elastic film 50 and the third layer 57 reduces the occurrence of cracks and suppresses the spread of the cracks.

### Other Embodiments

Although exemplary embodiments of the invention have been described, the invention is not limited to those embodiments. For example, thin-film piezoelectric elements 300 of an actuator device is used as pressure generating elements to vary the pressures of the pressure generating chambers 12 in the first and the second embodiment. However, any type of pressure generating element can be used without particular limitation, including, for example, the element of a thick-film actuator device produced by bonding a green sheet and the element of a vertical vibration actuator device produced by alternately forming piezoelectric layers and electrode layers so as to expand and contract in the axis direction. An electrostatic actuator may be used as the pressure generating element. The electrostatic actuator generates static electricity between a vibration plate and an electrode to deform the vibration plate, thereby ejecting droplets through nozzle apertures.

In the first and the second embodiment, the piezoelectric elements 300 acting as pressure generating elements are disposed on the third layer 57. The pressure generating elements may be provided directly on the third layer 57 or with another member their between, as long as they are present over the third layer 57.

In the first and the second embodiment, a monocrystalline silicon substrate is used as the flow channel substrate 10. The monocrystalline silicon substrate may have a crystal plane orientation of (100) or (110). Also, a SOI substrate or a glass substrate may be used without limiting to a monocrystalline silicon substrate.

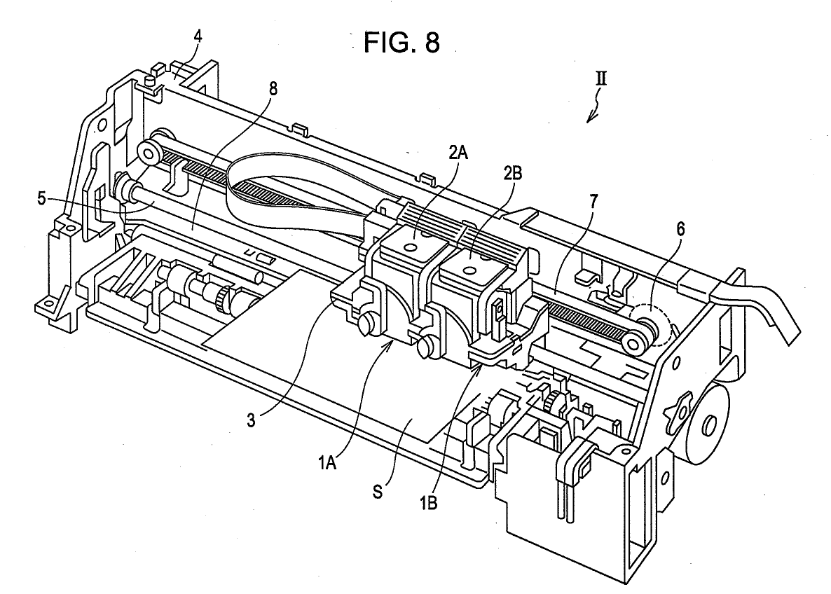

The ink jet recording head according to any one of those embodiments of the invention is installed in an ink jet recording apparatus to serve as a part of a recording head unit including a flow channel communicating with an ink cartridge or the like. FIG. 8 is a schematic perspective view of an ink jet recording apparatus including the ink jet recording head.

The ink jet recording apparatus II shown in FIG. 8 includes recording head units 1A and 1B each including the ink jet recording head I, and cartridges 2A and 2B for supplying ink are mounted in the respective recoding head units 1A and 1B. The recording head units 1A and 1B are loaded on a carriage 3 secured for movement along a carriage shaft 5 of an apparatus body 4. The recording head units 1A and 1B eject, for example, a black ink composition and a color ink composition, respectively.

The carriage 3 on which the recording head units 1A and 1B are mounted is moved along the carriage shaft 5 by transmitting the driving force from a driving motor 6 to the carriage 3 through a plurality of gears (not shown) and a timing belt 7. In the apparatus body 4, a platen 8 is disposed along the carriage shaft 5 so that a recording sheet S being a print medium, such as paper, fed from a paper feed roller or the like (not shown) is transported over the platen 8.

Although the first embodiment and the second embodiment have described an ink jet recording head as the liquid ejecting head, the invention is intended for all types of liquid ejecting head, and may be applied to other liquid ejecting heads ejecting liquid other than ink. Other liquid ejecting heads include various types of recording heads used in image recording apparatuses such as printers, color material ejecting heads used for manufacturing color filters of liquid crystal displays or the like, electrode material ejecting heads used for forming electrodes of organic EL displays or FEDs (field emission displays), and bioorganic material ejecting heads used for manufacturing bio-chips.

Also, other types of actuator device may be used without particular limitation to the type used in the above embodiments.

1. A liquid ejecting head comprising: a first layer essentially composed of silicon oxide disposed over a substrate; a second layer essentially composed of zirconium oxide formed by depositing zirconium on the first layer and thermally oxidizing the zirconium; a third layer essentially composed of zirconium oxide deposited on the second layer by sputtering; and a pressure generating element disposed over the third layer.

2. The liquid ejecting head according to claim 1, wherein the third layer has a thickness equal to or larger than the thickness of the second layer.

3. A liquid ejecting apparatus comprising the liquid ejecting head as set forth in claim 1.

4. An actuator device comprising: a first layer essentially composed of silicon oxide disposed over a substrate; a second layer essentially composed of zirconium oxide formed by depositing zirconium on the first layer and thermally oxidizing the zirconium; a third layer essentially composed of zirconium oxide deposited on the second layer by sputtering; and a pressure generating element disposed over the third layer.

5. A method for manufacturing a liquid ejecting head, comprising: forming a zirconium layer essentially composed of zirconium on a silicon oxide-based first layer disposed over a substrate; thermally oxidizing the zirconium layer to form a second layer essentially composed of zirconium oxide; and depositing zirconium oxide on the second layer by sputtering, thereby forming a third layer essentially composed of zirconium oxide.

6. A method for manufacturing a liquid ejecting head, comprising: forming a zirconium layer essentially composed of zirconium on a silicon oxide-based first layer disposed over a substrate; depositing zirconium oxide on the zirconium layer by sputtering, there by forming a third layer essentially composed of zirconium oxide; and subsequently thermally oxidizing the zirconium layer to form a second layer essentially composed of zirconium oxide.

7. The method according to claim 5, further comprising forming a piezoelectric element by forming a first electrode, a piezoelectric layer and a second electrode over the third layer after forming the second layer and the third layer.

8. The method according to claim 6, further comprising forming a piezoelectric element by forming a first electrode, a piezoelectric layer and a second electrode over the third layer after forming the second layer and the third layer.
